(19) United States
(12) Patent Application Publication
(10) Pub. No.: US 2008/0048753 A1
(43) Pub. Date: Feb. 28, 2008

(54) Differential Reshaping Circuit

(75) Inventors: Ahmed Gasmi, Boissy Saint Leger (FR); Jean Hourany, Amblie (FR)

Correspondence Address: PHILIPS ELECTRONICS NORTH AMERICA CORPORATION;INTELLECTUAL PROPERTY & STANDARDS, 370 W. TRIMBLE ROAD MS 91/MG, SAN JOSE, CA, 95131, US

(73) Assignee: Koninklijke Philips Electronics N.V., Eindhoven (NL)

(21) Appl. No.: 10/500,619

(22) PCT Filed: Dec. 18, 2002
(86) PCT No.: PCT/IB02/05619

§ 371 Date: Jun. 30, 2004

(30) Foreign Application Priority Data
Dec. 28, 2001 (EP) 01403383.1

(51) Int. Cl. H03K 19/094

(52) U.S. Cl. 327/333

(57) ABSTRACT

An amplifier circuit for regenerating complementary digital signals which comprises a differential pair of transistors (T5, T6). This circuit also comprises a pair of push-pull amplifiers (12a, 12b) which consists of a first and a second push-pull amplifier having a first and a second low input (L, Lb) which are coupled to a source for the input signal and its complement, respectively, a first and a second high input (H, Hb) which are coupled to a source of the complementary input signal and to a source of the input signal, respectively, a first and a second output (13a, 13b) which supply, under a low impedance and during switching, brief and intense current pulses of said complementary input signals of increased amplitude in order to apply these pulses to the first second control inputs (1a, 1b) of the first and second transistors (T5, T6) of the differential pair, respectively.

The invention relates to an electronic circuit for the reshaping of input signals, notably digital signals. The invention relates more specifically to an integrated circuit which includes field effect transistors such as metal semiconductor field effect transistors (MESFETs), that is, high electronic mobility, pseudo-morphic or metamorphic transistors (HEMT, PHEMT, MHEMT, respectively). Such transistors can be realized by means of technologies utilizing III-V materials, for example, GaAs, GaInAs, InP. The invention can be used, for example, in the field of high-speed digital telecommunications for the reshaping of a signal before its conversion into an optical signal.

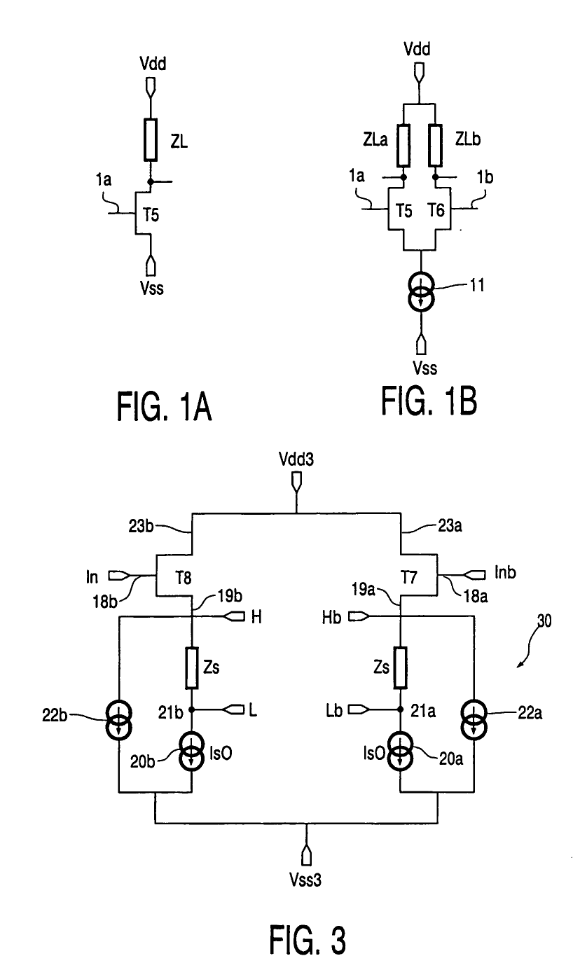

A field effect transistor stage is described in the publication “GaAs FET PRINCIPLES and TECHNOLOGY” edited by James V. DiLorenzo and Deen D. Khandelwal, ARTECH HOUSE, INC., 610 Washington Street, Dedham, Mass. 02026, United States of America. As described on the pages 621 to 623 of the cited document and illustrated in FIG. 1 on page 622 of the cited document or in the FIG. 1A attached to the present description, this stage is an inverter circuit which constitutes the basic unit of logic circuits. Using this basic unit, AND, OR, NAND and NOR functions can be realized. The inverter includes a switching transistor in series with a load. The negative terminal of the supply voltage V_{DD}, that is, the voltage applied to the source of the transistor, is connected to ground. The transistor is conductive when its gate receives an input voltage which has a high value V₁=V_{IH} corresponding to the logic state “1” and exceeds a threshold voltage V_{T}. In that case the output voltage of the transistor, as available on its drain, has a low value, that is, V₀-V_{OH}, which is near zero because the resistance of the transistor is small in comparison with the load resistance. The transistor is turned off when the input voltage is low, that is, V₁=V_{IL}, corresponding to the logic state “0”, and smaller than the threshold voltage V_{T}. The output voltage V₀=V_{OH} is then close to the supply voltage V_{DD} in the case where no current at all is required at the output node.

In relation to this state of the art, the invention has for its object to realize a circuit for regenerating a digital input signal into an output signal which has a short switching time and presents, moreover, the properties of stability and robustness.

Hereinafter, for the sake of simplicity a high transistor and a low transistor will be represented by two transistors whose electrodes are biased to a voltage potential which is higher for the so-called “high transistor” than for the so-called “low transistor”. Similarly, in the case of a connection with two inputs, for the sake of simplicity the high input and the low input will be represented by a so-called high input whose voltage potential is higher than that of the so-called low input. In the accompanying figures the high transistors and the high inputs are shown above the corresponding low transistors and low inputs.

The invention proposes a differential amplifier stage structure which is intended to form an output signal which is a signal regenerated on the basis of an input signal and a complementary signal which is the complement of this input signal and is formed on the basis of the input signal. Means for producing a complementary signal for a signal are known per se and are not described in detail herein.

The amplifier forming the object of the invention includes an input stage which comprises a pair of push-pull amplifiers having a pair of low transistors, referred to as the first and the second low transistor, and a pair of high transistors which are referred to as the first and the second high transistor. The association of the first low transistor and the first high transistor constitutes a first push-pull amplifier having a low input and a high input and a first output. The same holds for the second transistors of each pair. The input stage is thus formed by a pair of push-pull amplifiers which are referred to as the first and the second push-pull amplifier. The low control input of the first low transistor of the pair of low transistors receives a signal which is the complement of that received by the low control input of the second low transistor. The same holds for the inputs of the high transistors. Because the amplifiers are push-pull amplifiers, the input signal received by the high input of the high transistor of the first push-pull amplifier is the complement of the input signal received by the low input of the first low transistor of said push-pull amplifier. The same holds for the high and low transistors of the second push-pull amplifier. Each of the first and second outputs of the first and the second push-pull amplifier is coupled to an input of a differential pair whose output carries an output signal which is a signal regenerated on the basis of the input signal. An output signal and a complementary output signal are present on the respective load impedance terminals (ZLa and ZLb).

The invention thus relates to a differential amplifier circuit for regenerating complementary digital signals, which circuit includes a differential pair of transistors which consists of a first and a second transistor, the first transistor of the pair having a first control input and a first and a second electrode and the second transistor of the pair having a second control input and a first and a second electrode, characterized in that the circuit comprises, upstream from the differential pair, a pair of push-pull amplifiers which consist of a first and a second push-pull amplifier, having a first and a second low input, respectively, coupled to a source of the complementary input signal and to a source of the input signal, respectively, a first and a second high input coupled to a source of the input signal and to a source of the complementary input signal, respectively, a first and a second output, the first and second outputs of the pair of push-pull amplifiers being coupled to the first and second control inputs of the first and second transistors of the differential pair, respectively. In one embodiment of the invention the transistors of the differential pair are field effect transistors. The transistors forming the high and low stages of each push-pull amplifier are preferably field effect transistors.

The invention will be described in detail hereinafter with reference to the attached diagrammatic drawings; therein:

FIG. 1A shows a known example of a common-source digital signal amplifier;

FIG. 1B shows a further common-source digital signal amplifier;

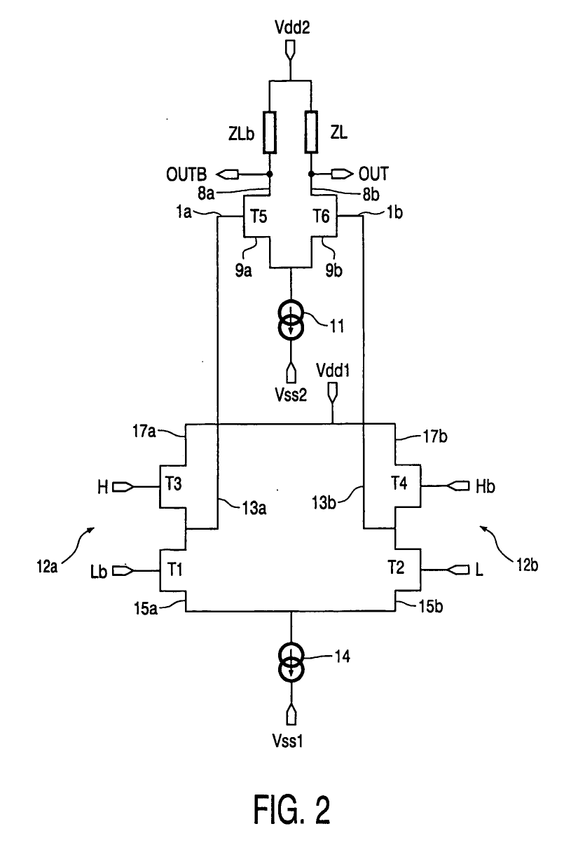

FIG. 2 shows a diagram of an embodiment of the invention, and

FIG. 3 shows an adaptation stage which may be provided at the input of the circuit shown in FIG. 2.

Referring to the FIGS. 1A and 1B, in order to realize a reshaping function in digital form use can be made of a basic unit which is formed by a fast amplifier stage having a low linear gain of, for example, between 0 and 10 dB, and operating in the switching mode so as to saturate the high and low levels of the signal, thus regenerating the levels which are referred to as the logic levels 1 and 0. The voltage swing between these two logic levels generally lies between 10 mV and 2 V. A typical value is, for example, 500 mV. This amplifier stage may be an amplifier with transistors connected in a common-source arrangement (to ground) with a single output as shown in FIG. 1A, or a common-source differential amplifier with virtual ground as shown in FIG. 1B. In FIG. 1A an input signal is applied to the gate 1a of a transistor T5 whose source is coupled to a voltage source Vss while its drain is connected to a voltage source Vdd via a load impedance ZL. The output signal is present on the terminals of said load ZL. In FIG. 1B an input signal is applied to the gate 1a of the transistor T5 and a complementary input signal is applied to the gate 1b of a transistor T6. The transistors T5 and T6 have a common source which is coupled to the same voltage source Vss, for example, via a current generator 11. The drains of the transistors T5 and T6 are connected to the load impedances ZLa and ZLb, respectively. The other two ends of these loads are connected to one another so as to form a common node which is coupled to the same voltage source Vdd. The output signal and the complementary output signal are present on the terminals of each of the load impedances ZLa and ZLb, respectively. These amplifiers may be connected in a cascade in the single or the differential mode. In that case a stage for adapting the impedance and for shifting the voltage level may be inserted between the digital amplifier stages. For the regeneration of a signal it is sufficient when the gain level of each of the amplifier stages is high enough to bring the high and low levels of the signal in the saturation range, thus reshaping the edges, regenerating the logic levels, and attenuating the noise on the logic levels. Consequently, the linear gain of each stage may be comparatively low, that is, typically between 0 and 10 dB. An advantage of a reduction of the linear gain resides in the fact that it enables an increase of the width of the passband. In the signal processing or regenerating functions utilizing differential pairs as the basic structure, the logic level 1 is defined by the level Vdd of the drain voltage which is the high voltage level, possibly with a constant voltage shift. The voltage swing sw between the high logic level and the low logic level is defined as sw=I0*ZL, where I0 is the total peak-to-peak current flowing in the impedance loads ZL of the differential pair. This current, being drawn from the supply source Vdd of the impedance loads ZL of the differential pair does not vary as a function of the logic state prevailing on this pair. It follows therefrom that the impedance of the path between the supply source Vdd and the common node of the two impedance loads ZL no longer varies. Therefore, the differential pair is not affected by the physical realization of the path between the supply source Vdd and the common node of the two impedance loads ZL. Moreover, the current I0, which may be fixed by a current generator inserted between the common source of T5 and T6 and the voltage source Vss, may be defined as a function of parameters which are technologically very stable, for example, by utilizing a current mirror. As a result, the logic circuits utilizing differential pairs as their basic structure have constant and stable logic levels 1 and 0, meaning that they are hardly sensitive to fluctuations of parameters such as the temperature, the supply voltage and the range of tolerances imposed by the relevant technology. A drawback encountered during the use of the described stages for regenerating the levels is due to the fact that the switching times are too long for the application considered.

FIG. 2 shows a differential amplifier circuit for regenerating mutually complementary digital signals in accordance with the invention. This circuit includes a differential pair of transistors T5, T6 which are, for example, field effect transistors. The first transistor TS and the second transistor T6 of the differential pair both have a first source 9aand 9b, respectively, a first drain 8a and a second drain 8b, respectively, and a first gate 1a and a second gate lb, respectively. In accordance with the invention the differential amplifier circuit comprises, connected upstream from the differential pair, a pair of push-pull amplifiers which consists of a first push-pull amplifier 12a and a second push-pull amplifier 12b, having a first low input Lb and a second low input L, respectively, which are coupled to a source of the complementary input signal and to a source of the input signal, respectively, and a first high input H and a second high input Hb which are coupled to a source of the input signal and to a source of the complementary input signal, respectively. The push-pull amplifiers 12a, 12b have a first output 13a and a second output 13b. The outputs 13a, 13b are coupled to the first gate 1a and the second gate 1b of the first transistor T5 and the second transistor T6 of the differential pair, respectively. The regenerated signal is present on the output OUT of the transistor T6, that is, on the drain 8b of this transistor. The complementary regenerated signal is present on the output OUTB of the transistor T5, that is, on the drain 8a of this transistor.

Each of the push-pull amplifiers 12a, 12b in the example shown in FIG. 2 is composed of two field effect transistors T1, T3 and T2, T4, respectively, that is, a first low transistor T1 and a second low transistor T2, respectively, and a first high transistor T3 and a second high transistor T4, respectively. Preferably, the low transistors T1, T2 are matched, meaning that they have characteristics which are as identical as possible. The same holds for the high transistors T3, T4. The push-pull amplifier thus formed is referred to as a differential push-pull amplifier. The first output 13a of the differential push-pull amplifier is formed by a connection node between the source of the first high transistor T3 and the drain of the first low transistor T1. The second output 13b of the differential push-pull amplifier is formed by a connection node between the source of the second high transistor T4 and the drain of the second low transistor T2. It is to be noted that the complementary commands for the differential pair T5, T6 involve pulses of opposite direction. The simultaneity of the pulses is very high. It is stimulated by the differential structure of the proposed push-pull amplifier. The drains 17a, 17b of each of the high transistors T3, T4 of the push-pull amplifiers 12a, 12b are connected to a first drain voltage source Vdd1. The drains 8a, 8b of each of the transistors T5, T6 of the differential pair are connected to a second drain voltage source Vdd2, that is, via impedances ZLb and ZL, respectively. The biasing of the sources 15a, 15b of each of the low transistors T1, T2 of the push-pull amplifiers 12a, 12b is ensured by the fact that these sources 15a, 15b are connected to a first source voltage source Vss1 via a first current generator 14. The biasing of the sources 9a, 9b of each of the transistors T5, T6 of the differential pair is ensured by the fact that these sources are connected to a second source voltage source Vss2 via a second current generator 11. The first or the second generator 11, 14 for the biasing of the sources may be an ideal generator or not. These generators may also be replaced or complemented by an impedance.

At the instant of transition of the control signals, the push-pull amplifiers 12a, 12b amplify the digital signal while increasing its amplitude. The typical amplitude at the output of the push-pull amplifier may be, for example, from 1 to 2 V. The differential pair formed by the transistors T5 and T6 then receives a signal of high amplitude. The switching time of the transistors T5 and T6 is then dependent essentially on the capability of the feeding stage to supply the brief but intense transitory currents required for the fast switching of the transistors T5 and T6. The use of the differential push-pull amplifier for guiding the differential pair formed by the transistors T5 and T6 thus enables a low impedance to be presented to the gates 1a, 1b of the transistors of this differential pair and to deliver the required brief but intense current pulses during switching. These current pulses are larger than those obtained by means of more conventional stages claimed to be of low impedance, for example, voltage followers. These current pulses, added to the high amplitude of the applied signal, enable much faster switching of the differential pair formed by the transistors T5 and T6.

The above description has been given with reference to an embodiment of the invention which includes field effect transistors as shown in FIG. 2. The invention can also be carried out, for example, by means of bipolar transistors, for example, NPN transistors. In that case the sources have to be replaced by the emitters, the drains by the collectors and the gates by the bases of these NPN transistors. The invention can also be realized by means of PNP transistors by making the necessary adaptations which are known to those skilled in the art.

The differential pair T5, T6 may be either a single differential pair as described above or a differential pair which is integrated in a more complex function, that is, in dependence on the techniques used in logic circuits with source-coupled field effect transistors (SCFL). As the SCFL gates comprise several imbricated differential pairs, the invention can be used to control all or some of the differential pairs. This enables an increase of the maximum yield that can be achieved in a given technology.

An adaptation stage can be used to control the differential amplifier. Such an adaptation circuit preferably has a low output impedance and delivers, on the basis of the input signal and a complementary signal which is the complement of said input signal, complementary high and low signals which are shifted relative to one another by a potential difference which is suitable for correctly biasing the low and high inputs of the pair of push-pull amplifiers. By way of example, the potential difference between the high and low inputs may be of the order of magnitude of from 1 to 2 V, whereas the swing between logic levels may be, for example, between 200 and 600 mV.

By way of example, an adaptation circuit of this kind comprises a pair of transistors T7, T8, each of which has a control input and electrodes. Hereinafter, this pair of transistors will be referred to as the follower pair. One of the control inputs of the transistors T7, T8 of the follower pair receives the input signal while the other control input receives a signal which is the complement of this input signal. Each transistor T7, T8 of the follower pair is connected so that one of the electrodes carries a follower signal of the signal received on its control input. This electrode is coupled to an input of means for changing the level of the signal present on this electrode. A signal present on an output of these means for changing the level is a signal which has the same logic value as the signal present on the input of these means but exhibits a shift of the voltage level, and the low and high complementary signals feeding the low and high inputs of the pair of push-pull amplifiers are thus formed by connection nodes present at the input and at the output of said level changing means.

FIG. 3 shows an example of such an adaptation circuit 30. The circuit 30 comprises essentially a follower pair of transistors T7, T8. For example, the transistors are of the field effect type as shown in FIG. 3. These transistors T7, T8 are connected as a source follower. Therefore, the circuit 30 is a circuit for lowering the impedance. On its gate l8a the first transistor T7 of the follower pair receives a signal Inb which is the complement of an input signal In to be regenerated, which signal In itself is received on the gate 18b of the second transistor T8 of the follower pair. The sources 19a, 19b of the transistors T7, T8 are coupled to third current sources 20a, 20b, respectively, of the adaptation circuit which themselves are connected to a third source voltage Vss3. Each of the sources 19a, 19b is coupled to its third current generator 20a, 20b, respectively, via an impedance Zs. The impedances Zs and the current generator 20a, 20b associated with each source change the level of the follower signal present on the input of the impedance Zs. In the example shown, the signal present on the output of the means for changing the level, that is, at the side of the impedance Zs which is not connected to the source 19a, 19b, is a signal which has the same logic value but a voltage potential which is much lower than that of the signal present on the input of the level changing means, that is, at the side of the impedance Zs which is connected to the source 19a, 19b. The drains 23a, 23b of each of the transistors T7, T8 are connected to a third drain voltage source Vdd3. The connections of this adaptation circuit 30 to the circuit shown in FIG. 2 will now be described. The connection point 19a of the source of the transistor T7 and the impedance of the load Zs connected to the source 19a carries the high signal Hb. The source 19a of the transistor T7 is thus connected to the high input Hb of the high transistor T4 of the second amplifier 12b of the pair of push-pull amplifiers. A connection point 21a at the output of the load impedance Zs of the transistor T7 carries the signal Lb. The point 21a is thus connected to the input Lb of the low transistor T1 of the first push-pull amplifier 12a of the pair of push-pull amplifiers. In a symmetrical fashion the point 19b which carries the high input signal H is connected to the input H of the high transistor T3 of the first push-pull amplifier 12a of the pair of push-pull amplifiers. Finally, a connection point 21b between the load impedance Zs of the second transistor T8 of the follower pair and the first current generator 20b, carrying the low signal L, is connected to the input L of the low transistor T2 of the second amplifier 12b of the pair of push-pull amplifiers. Optionally, fourth current generators 22a, 22b of the adaptation circuit 30 are connected between the sources 19a, 19b and the third source voltage source Vss3, respectively.

The nodes provided for the voltage supplies Vdd1, Vdd2 and Vdd3 of the drains of the push-pull amplifiers 12a, 12b, of the differential pair T5, T6 and of the transistors T7, T8 of the adaptation circuit 30, respectively, may be biased to different or equal voltage values; the same holds for the supply nodes Vss1, Vss2 and Vss3. In order to reduce the number of supply voltages, therefore, it is possible to connect on the one hand Vdd1, Vdd2 and Vdd3 to an overall supply Vdd and to connect on the other hand Vss1, Vss2 and Vss3 to an overall supply Vss. Moreover, either one of these supplies Vdd or Vss may be connected to ground, thus enabling the realization of a device with a single supply voltage.

The operation of the circuit in accordance with the invention is as follows.

The low and high signals to be regenerated as well as their complements are applied to the corresponding inputs of the pair of push-pull amplifiers. The signal on the output of these amplifiers 12a, 12b has an amplitude which is larger than the voltage swing between the logic high and low levels. As a result of this higher amplitude of the signal, the switching of the transistors of the differential pair is faster, that is, faster as the push-pull amplifier whose output impedance is low is more capable of supplying the brief but intense transitory currents required for the transistors of the differential pair during the switching.

The advantages of the push-pull structure are inter alia: a low output impedance and the possibility of supplying large transitory currents are thus combined with the advantages of differential connections which are inter alia: stability and precision of the logic levels, strong rejection of the supply voltage, strong reduction of parasites induced by the signal on the supplies Vdd and Vss, and little sensitivity to the range of tolerances of the relevant technology.

The described circuit can be advantageously used in the field of high-speed telecommunication devices.

The circuit is suitable in particular for use in a signal receiving/transmission module for optical fibers, which module comprises a circuit for reshaping signals and a multiplexing circuit which includes such a differential amplifier circuit.

1. A differential amplifier circuit for regenerating complementary digital signals, which circuit includes a differential pair of transistors whose inputs receive complementary digital signals and whose outputs deliver regenerated complementary signals, characterized in that it comprises means for reducing the switching time and for increasing the amplitude of the voltage swing between the high and low logic levels of the transistors of the differential pair, which means comprise a pair of push-pull amplifiers whose inputs receive the complementary input signals to be regenerated and whose outputs deliver, under a low impedance and during the switching, brief and intense current pulses of said complementary input signals of increased amplitude in order to apply these pulses to the inputs of said differential pair of transistors.

2. A circuit as claimed in claim 1, in which the differential pair of transistors includes a first transistor and a second transistor, the first transistor of the pair having a first input for control and a first electrode and a second electrode, the second transistor of the pair having a second input for control and a first electrode and a second electrode, the differential pair of push-pull amplifiers, connected upstream from the differential pair, comprising a first push-pull amplifier and a second push-pull amplifier, having a first and a second low input, respectively, coupled to a source of the complementary input signal and to a source of the input signal, respectively, a first and a second high input coupled to a source of the input signal and to a source for the complementary input signal, respectively, a first and a second output, the first and second outputs of the pair of push-pull amplifiers being coupled to the first and the second control inputs of the first and second transistors of the differential pair, respectively.

3. A circuit as claimed in claim 1 in which each amplifier of the pair of push-pull amplifiers comprises two transistors, each of which comprises a control input said control inputs forming the first and second low inputs and the first and second high inputs of the pair of push-pull amplifiers.

4. A circuit as claimed in claim 3, characterized in that the transistors of the differential pair and the transistors, together forming the pair of push-pull amplifiers are field effect transistors whose first and second electrodes are the sources and the drains, the control inputs being the gates of the transistors, the drains of the high transistors of each of the push-pull amplifiers of the pair of push-pull amplifiers being coupled to a first drain bias source, the drains of the transistors of the differential pair being coupled to a second drain bias source the sources of the low transistors of each of the push-pull amplifiers of the pair of push-pull amplifiers being coupled to a first source voltage source and the sources of each of the transistors of the differential pair being coupled to a second source bias source.

5. A circuit as claimed in claim 4, in which each of the first and second source biases is formed by a current generator or an impedance connected to a voltage source respectively.

6. A circuit as as claimed in claim 1, which circuit also comprises, connected upstream from the pair of push-pull amplifiers an adaptation circuit for lowering the impedance which delivers, on the basis of the input signal and a complementary signal which is the complement of said input signal, complementary low and high signals which feed the low and high inputs of the pair of push-pull amplifiers.

7. A circuit as claimed in claim 6, in which the adaptation circuit includes a follower pair of transistors, each of which has a control input and electrodes, one of the control inputs of the transistors of the follower pair receiving the input signal whereas the other control input receives a complementary signal which is the complement of this input signal, respectively, each transistor of the follower pair being connected in such a manner that one of its electrodes carries a follower signal of the signal received on its input, which electrode is coupled to an input of means for changing the level of the signal present on this electrode, a signal present on an output of these means being a signal which has the same logic value as the signal present on said input of said means but a shifted voltage potential, the low and high inputs of the pair of push-pull amplifiers being formed by the connection nodes present at the input and at the output of said means for changing the level.

8. An emission/transmission circuit for telecommunication, including an amplifier circuit as claimed in claim 1.

9. An emission module for the transmission/reception of signals via optical fibers, comprising a circuit for reshaping signals and a multiplexing circuit, including an amplifier circuit as claimed in claim 1.
